(19) United States
(12) Patent Application Publication
(10) Pub. No.: US 2025/0349812 A1
(43) Pub. Date: Nov. 13, 2025

(54) SEMICONDUCTOR PACKAGE AND MANUFACTURING METHOD OF THE SEMICONDUCTOR PACKAGE

(71) Applicant: SAMSUNG ELECTRONICS CO., LTD., SUWON-SI (KR)

(72) Inventors: Hyunsoo CHUNG, Suwon-si (KR); Kwang-Soo KIM, Suwon-si (KR)

(21) Appl. No.: 18/960,258

(22) Filed: Nov. 26, 2024

(30) Foreign Application Priority Data
May 10, 2024 (KR) 10-2024-0062103

(51) Int. Cl. H01L 25/18; H01L 21/304; H01L 21/56; H01L 23/00; H01L 23/31; H01L 23/498; H01L 23/538; H10B 80/00

(52) U.S. Cl. CPC H01L 25/18; H01L 21/304; H01L 21/565; H01L 23/3121; H01L 23/3135; H01L 23/5385; H01L 24/16; H01L 24/48; H01L 24/49; H01L 24/73; H01L 23/49838; H01L 24/32; H01L 2224/16227; H01L 2224/32225; H01L 2224/4805; H01L 2224/48227; H01L 2224/4903; H01L 2224/73253; H01L 2224/73257; H01L 2224/73265; H01L 2924/1431; H10B 80/00

(57) ABSTRACT

A semiconductor package includes: a redistribution layer; a lower semiconductor chip disposed on the redistribution layer; an upper semiconductor chip stacked on the lower semiconductor chip; a lower molding layer covering the lower semiconductor chip; an upper molding layer covering the upper semiconductor chip; a first wire connecting the lower semiconductor chip and the redistribution layer to each other in a vertical direction; and a second wire connecting the upper semiconductor chip and the redistribution layer to each other in the vertical direction, wherein the second wire includes a first portion, a second portion, and a bonding surface, wherein the first portion is disposed in the lower molding layer, wherein the second portion is disposed in the upper molding layer, and wherein the first portion of the second wire and the second portion of the second wire are bonded to each other at the bonding surface.

### CROSS-REFERENCE TO RELATED APPLICATION

This application claims priority under 35 U.S.C. § 119 to Korean Patent Application No. 10-2024-0062103, filed in the Korean Intellectual Property Office on May 10, 2024, the disclosure of which is incorporated by reference herein in its entirety.

### TECHNICAL FIELD

The present inventive concept relates to a semiconductor package and a manufacturing method of the semiconductor package.

### DISCUSSION OF THE RELATED ART

With the development of the electronics industry, the demand for high functionality, high speed, and miniaturization of electronic components is increasing. In response to this trend, packaging technology is under development for mounting a plurality of semiconductor chips in one package.

A semiconductor package is an implementation of integrated circuit chips in a form that is suitable for use in electronic products. Typically, the semiconductor package is constructed by mounting the semiconductor chips on a printed circuit board (PCB) and electrically connecting them to the PCB and/or each other with wires and/or bumps.

With the recent development of the semiconductor industry, semiconductor packages are developing in various directions with the aim at miniaturization, weight reduction, and a reduction of manufacturing costs. In addition, as the application field expands to large-capacity storage means, etc., various types of semiconductor packages are emerging.

### SUMMARY

According to embodiments of the present inventive concept, a semiconductor package includes: a redistribution layer; a lower semiconductor chip disposed on the redistribution layer; an upper semiconductor chip stacked on the lower semiconductor chip; a lower molding layer having a thickness corresponding to a distance between an upper surface of the redistribution layer and an upper surface of the lower semiconductor chip, and covering the lower semiconductor chip; an upper molding layer having a thickness corresponding to a distance between an upper surface of the lower molding layer and an upper surface of the upper semiconductor chip, and covering the upper semiconductor chip; a first wire connecting the lower semiconductor chip and the redistribution layer to each other in a vertical direction; and a second wire connecting the upper semiconductor chip and the redistribution layer to each other in the vertical direction, wherein the second wire includes a first portion, a second portion, and a bonding surface, wherein the first portion is disposed in the lower molding layer, wherein the second portion is disposed in the upper molding layer, and wherein the first portion of the second wire and the second portion of the second wire are bonded to each other at the bonding surface.

According to embodiments of the present inventive concept, a semiconductor package includes: a redistribution substrate; a first semiconductor chip disposed on the redistribution substrate; a first molding layer disposed on the redistribution substrate and covering the first semiconductor chip; a redistribution layer disposed on the first semiconductor chip; a chip stack including a second semiconductor chip and a third semiconductor chip stacked on the second semiconductor chip, in an offset manner, on the redistribution layer; a second molding layer disposed below the third semiconductor chip and covering the second semiconductor chip; a third molding layer disposed on the second molding layer and covering the third semiconductor chip; a dummy chip disposed on one side of the chip stack; a metal layer disposed on the third molding layer; a first wire extending vertically to connect the second semiconductor chip to the redistribution layer; a second wire extending vertically to connect the third semiconductor chip to the redistribution layer; and a third wire extending vertically to connect the metal layer to the redistribution layer, wherein the first wire includes a bonding surface that is formed between the first wire and the redistribution layer, and each of the second wire and the third wire includes a bonding surface, which is formed at a boundary surface that is between the second molding layer and the third molding layer, and a bonding surface, which is formed at a boundary surface between the second molding layer and the redistribution layer.

According to embodiments of the present inventive concept, a manufacturing method for a semiconductor package includes: disposing a metal layer on a carrier substrate; disposing an upper memory chip on the carrier substrate; forming a first bonding wire connecting the upper memory chip and the metal layer to each other; forming an upper molding layer covering the upper memory chip and the first bonding wire; grinding a portion of the upper molding layer so that a cut surface of the first bonding wire is formed; offset stacking a lower memory chip with respect to the upper memory chip; bonding the cut surface of the first bonding wire and a second bonding wire to each other; forming a lower molding layer covering the lower memory chip and the second bonding wire; and grinding a portion of the lower molding layer so that a cut surface of the second bonding wire is formed.

### BRIEF DESCRIPTION OF THE DRAWINGS

FIG. 1 is a diagram illustrating a semiconductor package according to embodiments of the present inventive concept.

FIG. 2 is an enlarged view of a portion A of the semiconductor package of FIG. 1.

FIGS. 3, 4, 5, 6, 7, 8, 9, 10 and 11 are diagrams illustrating a process of manufacturing a semiconductor package according to embodiments of the present inventive concept.

FIGS. 12, 13, 14, 15 and 16 are diagrams illustrating a process of manufacturing a semiconductor package according to embodiments of the present inventive concept.

FIG. 17 is a diagram illustrating a semiconductor package according to embodiments of the present inventive concept.

FIG. 18 is a diagram illustrating a semiconductor package according to embodiments of the present inventive concept.

### DETAILED DESCRIPTION

A semiconductor package according to embodiments of the present inventive concept will be described in detail with reference to the accompanying drawings. In the figures and specification, like reference numerals may denote like elements or features, and thus, their descriptions may be omitted or briefly described. In the following description, singular expressions include plural expressions unless the context clearly dictates otherwise.

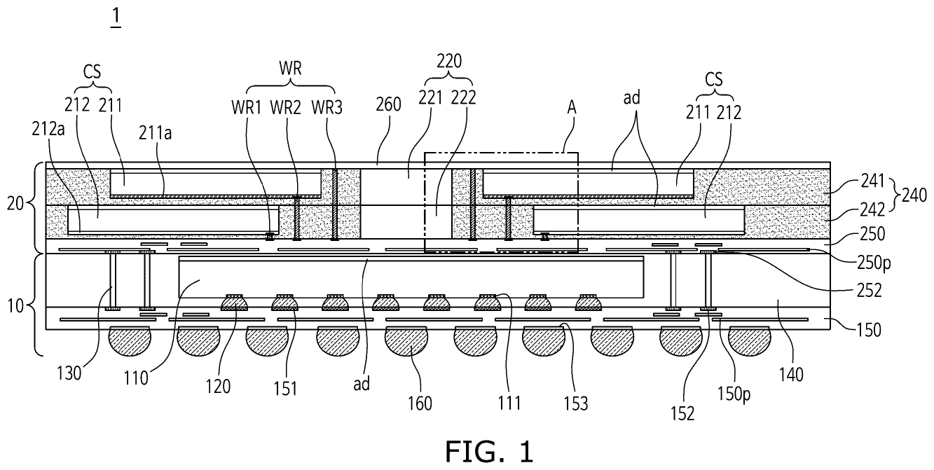

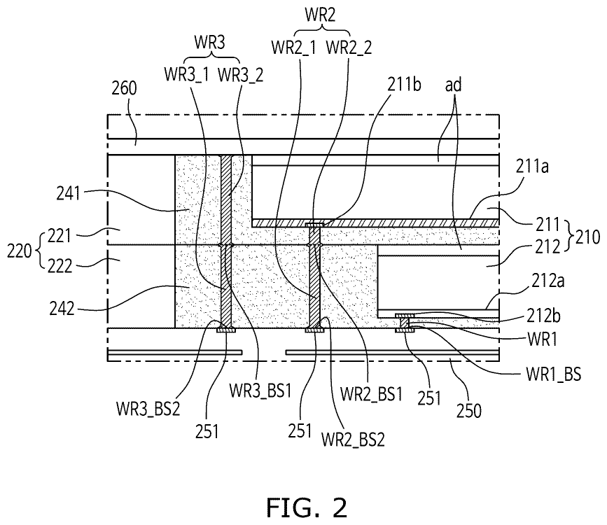

FIG. 1 is a diagram illustrating a semiconductor package according to embodiments of the present inventive concept. FIG. 2 is an enlarged view of a portion A of the semiconductor package of FIG. 1.

Referring to FIG. 1, a semiconductor package 1 according to embodiments of the present inventive concept may include a lower semiconductor package 10 and an upper semiconductor package 20.

A package substrate 150 may be provided in the lower semiconductor package 10. The package substrate 150 may be a redistribution substrate. The package substrate 150 may include at least two or more substrate wiring layers stacked on each other therein. The substrate wiring layer may be a wiring layer that is formed by patterning an insulating material layer and a conductive material layer. It is to be noted that the structure of the package substrate 150 is briefly illustrated for convenience of explanation.

The insulating pattern may include an inorganic insulating layer such as silicon oxide (SiO) or silicon nitride (SiN). In addition, the insulating patterns may include a polymer material. The insulating patterns 150p may include an insulating polymer or a photoimageable dielectric (PID). For example, the photosensitive polymer may include at least one of photosensitive polyimide, polybenzoxazole (PBO), phenol-based polymer, or benzocyclobutene-based polymer.

The semiconductor package 1 may have a fan-out structure by the package substrate 150. The package substrate 150 may include a conductive pattern 150p and an external pad 153.

The conductive pattern 150p may be connected to the external pad 153 that is disposed at a lower surface of the package substrate 150. An external terminal 160 may be disposed on the external pad 153.

The external pad 153 may be electrically connected to the conductive pattern 150p. For example, a protective layer may be disposed on the lower surface of the package substrate 150. The protective layer may cover the insulating patterns and the conductive patterns 150p, and may expose the external pad 153. The protective layer may include an insulating polymer such as an epoxy-based polymer, an azinomoto build-up film (ABF), an organic material, or an inorganic material.

The conductive pattern 150p may have a damascene structure. The conductive pattern 150p may include a conductive material. For example, the conductive pattern 150p may include copper (Cu). The conductive pattern 150p may redistribute a first semiconductor chip 110 that is mounted on the package substrate 150.

Upper pads 151 and 152 may be disposed on an upper surface of the package substrate 150. The upper pads 151 and 152 may be exposed at the upper surface of the package substrate 150. The conductive pattern 150p may be electrically connected to the upper pads 151 and 152. The upper pads 151 and 152 may include a first upper pad 151 and a second upper pad 152. The first upper pad 151 may be for mounting the first semiconductor chip 110 to be described below, and the second upper pad 152 may be connected to a connection terminal 130. The first upper pad 151 may be positioned below the first semiconductor chip 110, and the second upper pad 152 may be positioned outside the first semiconductor chip 110.

The first semiconductor chip 110 may be disposed on the package substrate 150. The first semiconductor chip 110 may be disposed on the upper surface of the package substrate 150. The first semiconductor chip 110 may be a logic chip, for example.

For example, the first semiconductor chip 110 may be disposed on the package substrate 150 in a face down manner. For example, the first semiconductor chip 110 may include a front surface facing the package substrate 150, and a rear surface that is opposite to the front surface. Hereinafter, the front surface may be an active surface of an integrated device in the semiconductor chip, on which the pad of the semiconductor chip is formed, and the rear surface may be a surface that is opposite to the front surface.

The first semiconductor chip 110 may include a chip pad 111 provided on a lower surface thereof. The chip pad 111 may be electrically connected to the integrated circuit of the first semiconductor chip 110.

The first semiconductor chip 110 may be mounted on the package substrate 150. The first semiconductor chip 110 may be mounted on the package substrate 150 in a flip chip manner. For example, the front surface of the first semiconductor chip 110 may face the package substrate 150. A chip terminal 120 may be provided below the first semiconductor chip 110. The chip terminal 120 may include a solder bump. The first semiconductor chip 110 may be mounted on the package substrate 150 through the chip terminal 120. The chip terminal 120 may connect the chip pad 111 of the first semiconductor chip 110 and the first upper pad 151 of the package substrate 150 to each other.

The lower semiconductor package 10 may include a first molding layer 140 (e.g., a logic chip molding layer). The first molding layer 140 may be provided on the package substrate 150. The first molding layer 140 may cover the upper surface of the package substrate 150.

The first molding layer 140 may cover the first semiconductor chip 110. When viewed in a plan view, the first molding layer 140 may at least partially surround the first semiconductor chip 110. For example, the first molding layer 140 may completely surround the first semiconductor chip 110. The first molding layer 140 may cover side surfaces of the first semiconductor chip 110. An upper surface of the first molding layer 140 and the rear surface of the first semiconductor chip 110 may be substantially coplanar.

The first molding layer 140 may fill a space that is between the package substrate 150 and the first semiconductor chip 110. The first molding layer 140 may at least partially surround the chip terminal 120 that is disposed between the package substrate 150 and the first semiconductor chip 110. For example, the first molding layer 140 may completely surround the chip terminal 120 that is disposed between the package substrate 150 and the first semiconductor chip 110. The first molding layer 140 may include an insulating material such as an epoxy molding compound (EMC).

A redistribution layer 250 may be disposed on the first molding layer 140. The redistribution layer 250 may cover the first molding layer 140 and the first semiconductor chip 110. For example, the redistribution layer 250 may be in contact with the upper surface of the first molding layer 140. The redistribution layer 250 may be adhered to the first semiconductor chip 110. For example, the first semiconductor chip 110 may include an adhesive layer ad that is disposed on the upper surface of the first semiconductor chip 110. The adhesive layer ad may adhere the first semiconductor chip 110 to the lower surface of the redistribution layer 250. The adhesive layer ad may include a die attach film (DAF).

The upper semiconductor package 20 may include a second semiconductor chip 212 (e.g., a lower memory chip), a third semiconductor chip 211 (e.g., an upper memory chip), and the redistribution layer 250.

The redistribution layer 250 may be a redistribution substrate. The redistribution layer 250 may include an insulating pattern and a conductive pattern 250p in the insulating pattern. The description of the conductive pattern 150p of the package substrate 150 may be equally applied to the conductive pattern 250p.

The redistribution layer 250 may include an upper pad 251 and a lower pad 252. The upper pad 251 may be disposed on the redistribution layer 250. The upper pad 251 may be positioned on an upper surface of the redistribution layer 250. The upper pad 251 may be electrically connected to the conductive pattern 250p. The upper pad 251 may be a pad for mounting the chip stack CS.

The redistribution layer 250 may be electrically connected to the package substrate 150 through the connection terminal 130. The connection terminal 130 may be included in the lower semiconductor package 10. For example, the connection terminal 130, which connects the redistribution layer 250 and the package substrate 150 to each other, may be provided on one side of the first semiconductor chip 110.

The connection terminal 130 may include a conductive post (e.g., a Cu post) directly connecting the second upper pad 152 of the package substrate 150 to the lower pad 252 of the redistribution layer 250. In addition, the connection terminal 130 might not use the conductive post, and may use wire bonding.

The connection terminal 130 may vertically pass through the first molding layer 140 from the second upper pad 152 of the package substrate 150 and may extend to the lower pad 252 of the redistribution layer 250. The connection terminal 130 may be positioned between the upper surface of the package substrate 150 and the lower surface of a redistribution layer 400, that is, while being buried in the first molding layer 140. For example, an angle formed between the connection terminal 130 and the second upper pad 152 of the package substrate 150 or the lower pad 252 of the redistribution layer 250 may be approximately 90 degrees.

The upper semiconductor package 20 may include one or more chip stacks CS on the redistribution layer 250. Although the aspect of FIG. 1 illustrates that the two semiconductor chips 211 and 212 are included in the chip stack CS, the present inventive concept is not limited thereto. The chip stack CS may include one, or three or more semiconductor chips. The following description will be described in detail with reference to the chip stack CS including two semiconductor chips 211 and 212.

The chip stack CS may include the semiconductor chips 211 and 212 stacked on each other. One of the semiconductor chips 211 and 212 of the chip stack CS, which is disposed at a lower side, is referred to as the second semiconductor chip 212, and the other semiconductor chip that is stacked on the second semiconductor chip 212 is referred to as the third semiconductor chip 211. For example, the second semiconductor chip 212 may be disposed between the third semiconductor chip 211 and the redistribution layer 250. In addition, each semiconductor chip may be referred to as the lower semiconductor chip or the upper semiconductor chip according to the relative position of each semiconductor chip in the chip stack CS. For example, the second semiconductor chip 212 may correspond to the lower semiconductor chip, and the third semiconductor chip 211 may correspond to the upper semiconductor chip.

In the present embodiment, the second semiconductor chip 212 may refer to a semiconductor chip that is disposed at the lowermost end of the chip stack CS for convenience of explanation. The second semiconductor chip 212 and the third semiconductor chip 211 may be the same type of semiconductor chip as each other, or may be different types of semiconductor chips from each other, respectively. For example, the second semiconductor chip 212 and the third semiconductor chip 211 may be memory chips such as DRAMs, SRAMs, MRAMs, or flash memories. In addition, the second semiconductor chip 212 may be a logic chip, and the third semiconductor chip 211 may be a memory chip. In addition, the second semiconductor chip 212 may be a memory chip, and the third semiconductor chip 211 may be a logic chip.

In the present embodiment, the chip stack CS having one third semiconductor chip 211 is illustrated, but the present inventive concept is not limited thereto. The number of third semiconductor chips 211 stacked on the second semiconductor chip 212 may be two or more.

The second semiconductor chip 212 may be disposed on the redistribution layer 250 in a face down manner. For example, the second semiconductor chip 212 may include a front surface (e.g., an active surface) facing the redistribution layer 250, and a rear surface that is opposite to the front surface. The second semiconductor chip 212 may include a second chip pad 212b that is provided on the active surface 212a. The second chip pad 212b may be electrically connected to an integrated circuit of the second semiconductor chip 212.

The third semiconductor chip 211 may be disposed on the second semiconductor chip 212 in a face down manner. For example, the third semiconductor chip 211 may include a front surface (e.g., an active surface) facing the redistribution layer 250, and a rear surface that is opposite to the front surface. The third semiconductor chip 211 may include a third chip pad 211b that is provided on an active surface 211a. The third chip pad 211b may be electrically connected to an integrated circuit of the third semiconductor chip 211.

The second semiconductor chip 212 and the third semiconductor chip 211 may be disposed to form an offset stack structure. For example, the second semiconductor chip 212 and the third semiconductor chip 211 may be stacked to be offset from each other. For example, the second semiconductor chip 212 and the third semiconductor 211 may form a stepped shaped structure.

The second semiconductor chip 212 and the third semiconductor chip 211 may have a thickness of about 50 um. However, the present inventive concept is not limited thereto, and the thicknesses may vary according to the type of semiconductor chip that each of the second semiconductor chip 212 and the third semiconductor chip 211 is.

A portion of the lower surface of the third semiconductor chip 211 may be offset from the second semiconductor chip 212 as the second semiconductor chip 212 and the third semiconductor chip 211 are stacked in the offset stack structure. For example, a portion of the lower surface of the third semiconductor chip 211 might not overlap the second semiconductor chip 212. The lower surfaces of the second semiconductor chip 212 and the third semiconductor chip 211 may be active surfaces. For example, the second chip pad 212b of the second semiconductor chip 212 may be disposed on the lower surface of the second semiconductor chip 212, and the third chip pad 211b of the third semiconductor chip 211 may be provided on the offset surface of the third semiconductor chip 211. For example, the third chip pad 211b of the third semiconductor chip 211 may be provided on the portion of the lower surface of the third semiconductor chip 211 that does not overlap the second semiconductor chip 212.

Each of the positions of the second chip pad 212b and the third chip pad 211b may respectively correspond to an upper pad 251 of the redistribution layer 250. For example, each of the second chip pad 212b and the third chip pad 211b may face a corresponding upper pad 251. For example, each of the second chip pad 212b and the third chip pad 211b may be arranged to be vertically aligned or partially misaligned with a corresponding upper pad 252.

When a plurality of chip stacks CS are provided, offset stack directions of the chip stacks CS may be different from each other. The offset stack direction of each of the chip stacks CS may vary according to the arrangement of the upper pad 251 of the redistribution layer 250 and the arrangement of the second chip pad 212b and the third chip pad 211b of the chip stack CS. Referring to FIG. 1, each chip stack CS is illustrated to have an offset stacked structure in a direction toward the center of the semiconductor package 1, but the present inventive concept is not limited thereto. For example, the third semiconductor chip 211 may be offset from the second semiconductor chip 212 such that it is disposed to be closer to the center of the semiconductor package 1 than the second semiconductor chip 212.

The adhesive layer ad may be provided on the upper surface of the second semiconductor chip 212 and on the upper surface of the third semiconductor chip 211, respectively. The second semiconductor chip 212 and the third semiconductor chip 211 may be adhered to another second semiconductor chip 212 or third semiconductor chip 211 by using the adhesive layer ad. For example, if a plurality of third semiconductor chips 211 are stacked, the third semiconductor chips 211 may be adhered to each other through the adhesive layer ad. The lowermost third semiconductor chip 211 may be adhered to the second semiconductor chip 212 by using the adhesive layer ad. The uppermost third semiconductor chip 211 may be provided with an adhesive layer ad on an upper surface thereof and may be adhered to a metal layer 260 to be described below. The adhesive layer ad may include a die attach film (DAF).

The upper semiconductor package 20 may include a molding layer stack 240 that is formed on the redistribution layer 250.

The molding layer stack 240 is a structure for sealing or covering the chip stack CS. The molding layer stack 240 may have a stack structure corresponding to the stack structure of the chip stack. For example, if the chip stack CS is formed by stacking two semiconductor chips, the molding layer stack 240 may also have two layers. Each molding layer of the molding layer stack 240 may cover a corresponding semiconductor chip of the chip stack CS. For example, a lower molding layer 242 may cover the lower semiconductor chip 212, and an upper molding layer 241 may cover the upper semiconductor chip 211.

The molding layer stack 240 may include a lower molding layer or a second molding layer 242 formed on the redistribution layer 250, and an upper molding layer or a third molding layer 241 formed on the second molding layer 242. The second molding layer 242 and the third molding layer 241 may include the same material as each other. For example, the second molding layer 242 and the third molding layer 241 may include an insulating material such as an epoxy molding compound (EMC). The second molding layer 242 and the third molding layer 241 may be formed through separate processes, respectively.

The second molding layer 242 may cover the second semiconductor chip 212. The second molding layer 242 may cover a lower surface and a side surface of the second semiconductor chip 212. The upper surface of the second semiconductor chip 212 may be covered by a configuration other than the second molding layer 242. The upper surface of the second semiconductor chip 212 may be covered by the third molding layer 241. An upper surface of the second molding layer 242 may be substantially coplanar with the upper surface of the second semiconductor chip 212.

The second molding layer 242 may have a thickness corresponding to or similar to that of the second semiconductor chip 212. The second molding layer 242 may have a thickness corresponding to a distance between the upper surface of the redistribution layer 250 and the upper surface of the second semiconductor chip 212. For example, if the thickness of the second semiconductor chip 212 is about 50 μm, the thickness of the second molding layer 242 may be close to about 50 μm. For example, the second molding layer 242 might not cover the third semiconductor chip 211, and may cover the second semiconductor chip 212.

The third molding layer 241 may cover the third semiconductor chip 211. The third molding layer 241 may cover a lower surface and a side surface of the third semiconductor chip 211. The upper surface of the third semiconductor chip 211 may be covered by the metal layer 260. An upper surface of the third molding layer 241 may be substantially coplanar with the upper surface of the third semiconductor chip 211.

The third molding layer 241 may have a thickness corresponding to or similar to that of the third semiconductor chip 211. The third molding layer 241 may have a thickness corresponding to a distance between the upper surface of the second molding layer 242 and the upper surface of the third semiconductor chip 211. For example, if the thickness of the third semiconductor chip 211 is about 50 μm, the thickness of the third molding layer 241 may be close to about 50 μm.

The semiconductor chips 211 and 212 corresponding to each layer of the chip stack CS may be positioned in the molding layers 241 and 242, respectively. If the number of semiconductor chips in the chip stack CS increases, a semiconductor chip having a thickness corresponding to one molding layer may be positioned in each molding layer.

A portion of the third molding layer 241 may be positioned between the second semiconductor chip 212 and the third semiconductor chip 211. However, the present inventive concept is not limited thereto, and the third molding layer 241 may be formed to have the same thickness as the thickness of the third semiconductor chip 211 and the adhesive layer ad that is attached to the third semiconductor chip 211, and the third semiconductor chip 211 and the second semiconductor chip 212 may be in contact with each other.

The upper semiconductor package 20 may include the metal layer 260. The metal layer 260 may be disposed on an upper portion of the semiconductor package 1. The metal layer 260 may be positioned on top of the semiconductor package 1. For example, an upper surface of the metal layer 260 may correspond to an upper surface of the semiconductor package 1. The metal layer 260 may be disposed on an upper portion of the molding layer stack 240. For example, the metal layer 260 may be disposed on an upper portion of the third molding layer 241.

The metal layer 260 may shield the upper semiconductor package 20 and the lower semiconductor package 10 from electromagnetic waves. In addition, the metal layer 260 may also shield external components from the electromagnetic waves that may be generated from the semiconductor chips 110, 211, and 212 that are mounted inside the semiconductor package 1. For example, with the semiconductor package 1 mounted on the package substrate 150, the metal layer 260 may shield external devices from the electromagnetic waves that may be generated from the semiconductor chips 110, 211, and 212, and may shield the semiconductor chips 110, 211, and 212 from the electromagnetic waves that may be generated from the external devices.

With the metal layer 260, the semiconductor package 1 may prevent electrical functional failure such as weakening function and malfunction of the circuit due to interference of electromagnetic waves.

The metal layer 260 may include a metal having high conductivity or low resistance. For example, the metal layer 260 may include copper (Cu), aluminum (Al), etc.

A wire WR electrically connecting the chip stack CS and the redistribution layer 250 to each other will be described with reference to FIGS. 1 and 2.

The semiconductor package 1 may include a wire WR connecting the chip stack CS and the redistribution layer 250 to each other. The wire WR may include, for example, nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), etc.

The chip stack CS may be mounted on the redistribution layer 250. The second semiconductor chip 212 and the third semiconductor chip 211 may be electrically connected to the redistribution layer 250. For example, the second semiconductor chip 212 and the third semiconductor chip 211 may be mounted on the redistribution layer 250 by using wires WR2 and WR3.

The wire WR may include a first wire WR1 and a second wire WR2. The first wire WR1 connects the second chip pad 212b of the second semiconductor chip 212 to the upper pad 251 of the redistribution layer 250, and the second wire WR2 connects the third chip pad 211b of the third semiconductor chip 211 to the upper pad 251 of the redistribution layer 250. For example, the first wire WR1 directly connects the second chip pad 212b of the second semiconductor chip 212 to the upper pad 251 of the redistribution layer 250, and the second wire WR2 directly connects the third chip pad 211b of the third semiconductor chip 211 to the upper pad 251 of the redistribution layer 250.

The first wire WR1 may extend from a lower surface of the second chip pad 212b to an upper surface of the upper pad 251. The first wire WR1 and the upper pad 251 of the redistribution layer 250 may be connected to each other in an approximately vertical direction. The first wire WR1 and the second chip pad 212b of the second semiconductor chip 212 may be connected to each other in an approximately vertical direction.

The second wire WR2 may extend from a lower surface of the third chip pad 211b to the upper surface of the upper pad 251. The second wire WR2 and the upper pad 251 of the redistribution layer 250 may be connected to each other in an approximately vertical direction.

The second wire WR2 and the third chip pad 211b of the third semiconductor chip 211 may be connected to each other in an approximately vertical direction.

Hereinafter, by “vertical”, it might not necessarily refer to an angle of 90 degrees. In this illustration, the fact that the wires WR are connected vertically or in the vertical direction may mean that they are connected in the vertical direction even if there is a slight difference or change in direction. In addition, even if the wire WR is curved or bent, if the overall structure is maintained in the vertical direction, the wire WR may be considered to be connected vertically or in the vertical direction.

The wire WR may include a third wire WR3 connecting the metal layer 260 and the upper pad 251 of the redistribution layer 250 to each other.

The third wire WR3 may electrically connect the metal layer 260 and the upper pad 251 of the redistribution layer 250 to each other. The third wire WR3 may impart an electromagnetic wave shielding function to the metal layer 260. For example, the third wire WR3 may be an input and output terminal for the electromagnetic wave shielding function of the metal layer 260. A portion of the conductive pattern 250p redistributed through the redistribution layer 250 through the third wire WR3 may be connected to a ground pad. In addition, the metal layer 260 may be directly grounded.

The wire WR for the chip stack CS may vertically extend from the lower surfaces of the second semiconductor chip 212 and the third semiconductor chip 211 toward the upper surface of the redistribution layer 250. By vertically connecting the wire WR, the length of the wire WR may be reduced to the shortest distance, thereby improving the electrical characteristics of the semiconductor package 1. In addition, compared to using vias, etc., the manufacturing cost can be reduced and the manufacturing process can be facilitated.

In addition, the second semiconductor chip 212 and the third semiconductor chip 211 of the chip stack CS may be arranged face down, and the second semiconductor chip 212 and the third semiconductor chip 211 may also be vertically connected to each other using the wire WR. The wire WR having a small diameter may have a very small cross-sectional area, and may increase the degree of integration of the semiconductor package 1.

However, if the length of the wire WR exceeds a certain level, the sweeping, that is, a phenomenon in which the wire WR is swept may occur when the molding layer stack 240 is formed. It is desirable to prevent this, because the sweeping phenomenon may cause the wires WR to come into contact with each other, possibly resulting in an electrical short.

The wire WR of the present embodiment may have a bonding surface formed at each boundary of each mold layer in the molding layer stack 240. For example, if the wire WR is passed through the upper and lower surfaces of the second molding layer 242, bonding surfaces of the wire WR may each be formed on substantially the same planes as the upper and lower surfaces of the second molding layer 242. In addition, if the wire WR is passed through a lower surface of the third molding layer 241, the bonding surface of the wire WR may be formed on substantially the same plane as the lower surface of the third molding layer 241.

The bonding surface of the wire WR may be formed at a portion where the wires WR are connected to each other, or at a portion where the wire WR is connected to the upper pad 251 of the redistribution layer 250. In addition, the bonding surface of the wire WR may be a cut or a ground portion of the wire WR may be connected to a portion of another wire WR.

FIG. 2 illustrates that the bonding surface has a diameter that is greater than that of the wire WR, but the present inventive concept is not limited thereto. Even if the diameter of the bonding surface is equal to or smaller than the diameter of the wire WR, the surface may be referred to as the bonding surface as long as it is a surface of the wire WR that is connected to another wire WR.

The second wire WR2 and the third wire WR3 may include wire segments having a length corresponding to the thickness of each of the layers in the molding layer stack 240. The wire segments having a length corresponding to the thickness of each molding layer may refer to a wire segment extending in a direction that is substantially perpendicular to the upper surface or the lower surface of each molding layer. Each wire segment may be buried in each molding layer.

The third wire WR3 may include a first portion WR3_2 and a second portion WR3_2. The second portion WR3_2 may be buried in the third molding layer 241, and the first portion WR3_1 may be buried in the second molding layer 242. The second wire WR2 may include a wire segment having a length corresponding to that of the third molding layer 241. The second wire WR2 may include a second portion WR2_2 and a first portion WR2_1. The second portion WR2_2 may be buried in the third molding layer 241, and the first portion WR2_1 may be buried in the second molding layer 242.

The first portion WR3_1 and the second portion WR3_2 may be connected to each other along a longitudinal direction in which the third wire WR3 extends. The first portion WR2_1 and the second portion WR2_2 may be connected to each other along a longitudinal direction in which the second wire WR2 extends.

The second wire WR2 may include a bonding surface WR2_BS1 at which the first portion WR2_1 and the second portion WR2_2 are bonded to each other. The bonding surface WR2 BS1 at which the first portion WR2_1 and the second portion WR2_2 of the second wire WR2 are bonded to each other may be positioned at a boundary surface between the second molding layer 242 and the third molding layer 241. The bonding surface WR2 BS1 of the second wire WR2 may be substantially coplanar with the upper surface of the second molding layer 242 or the lower surface of the third molding layer 241.

The second wire WR2 may include a bonding surface WR2_BS2 at which the first portion WR2_1 and the redistribution layer 250 are bonded to each other. The bonding surface WR2_BS2 at which the second wire WR2 is connected to the redistribution layer 250 may be positioned on substantially the same plane as a bonding surface WR3_BS2 at which the third wire WR3 is connected to the redistribution layer 250. For example, the bonding surface WR2 BS2 at which the second wire WR2 is connected to the redistribution layer 250 may be substantially coplanar with the bonding surface WR3_BS2 at which the third wire WR3 is connected to the redistribution layer 250.

The third wire WR3 may include a bonding surface WR3_BS1 at which the first portion WR3_1 and the second portion WR3_2 are bonded to each other. The bonding surface WR3 BS1 at which the first portion WR3_1 and the second portion WR3_2 of the third wire WR3 are bonded to each other may be positioned at the boundary surface between the second molding layer 242 and the third molding layer 241. The bonding surface WR3_BS1 of the third wire WR3 may be substantially coplanar with the upper surface of the second molding layer 242 or the lower surface of the third molding layer 241.

The third wire WR3 may include a bonding surface WR3_BS2 at which the first portion WR3_1 and the redistribution layer 250 are connected to each other. The bonding surface WR3 BS2 at which the third wire WR3 is connected to the redistribution layer 250 may be positioned on substantially the same plane as a bonding surface WR2_BS2 at which the second wire WR2 is connected to the redistribution layer 250. For example, the bonding surface WR3 BS2 at which the third wire WR3 is connected to the redistribution layer 250 may be substantially coplanar with the bonding surface WR2_BS2 at which the second wire WR2 is connected to the redistribution layer 250. The bonding surfaces WR2_BS2 and WR3_BS2 may be positioned on substantially the same plane as a boundary surface between the second molding layer 242 and the redistribution layer 250.

The first wire WR1 may include a bonding surface WR1_BS connected to the redistribution layer 250. The bonding surface WR1_BS may be positioned at the boundary surface between the second molding layer 242 and the redistribution layer 250. The bonding surface WR1_BS at which the first wire WR1 is connected to the redistribution layer 250 may be positioned on substantially the same plane as the bonding surface WR2_BS2 at which the second wire WR2 is connected to the redistribution layer 250 and as the bonding surface WR3_BS2 at which the third wire WR3 is connected to the redistribution layer 250. The bonding surfaces WR1_BS, WR2_BS2, and WR3_BS2 at which the wire WR and the redistribution layer 250 are connected to each other may be positioned on substantially the same plane as the boundary surface between the second molding layer 242 and the redistribution layer 250.

Referring to FIG. 1, the semiconductor package 1 may include a dummy chip 220 for dissipating heat that is generated from the first semiconductor chip 110.

The dummy chip 220 may dissipate the heat that is generated from the first semiconductor chip 110 in a heat conduction manner. The dummy chip 220 may include, for example, silicon (Si), etc. The dummy chip 220 might not be electrically connected to the redistribution layer 250 or the package substrate 150. Note that another semiconductor chip electrically connected to the redistribution layer 250 or the package substrate 150 may be disposed instead of the dummy chip 220.

The dummy chip 220 may be provided in the upper semiconductor package 20. The dummy chip 220 may include a first dummy chip 222 (e.g., a lower dummy chip), which is disposed on the redistribution layer 250, and a second dummy chip 221 (e.g., an upper dummy chip), which is disposed on the first dummy chip 222. The metal layer 260 may be disposed on an upper side of the second dummy chip 221. The second dummy chip 221 may be adhered to the metal layer 260 through an adhesive layer ad.

The first dummy chip 222 may be covered by the second molding layer 242. In addition, the second dummy chip 221 may be covered by the third molding layer 241. The first dummy chip 222 and the second dummy chip 221 may have thicknesses corresponding to those of the second molding layer 242 and the third molding layer 241, respectively. For example, the first dummy chip 222 and the second dummy chip 221 may have thicknesses the same as or similar to those of the second molding layer 242 and the third molding layer 241, respectively.

For example, the first dummy chip 222 and the second dummy chip 221 may be disposed perpendicular to each other. The first dummy chip 222 and the second dummy chip 221 may be disposed to overlap with each other, at least in part. For example, like the chip stack CS, the first dummy chip 222 and the second dummy chip 221 may be offset stacked.

In the first semiconductor chip 110, heat may be generated the most from a central portion of the first semiconductor chip 110. Accordingly, the first dummy chip 222 and the second dummy chip 221 may be positioned on the central portion of the first semiconductor chip 110. For example, at least a portion of the dummy chip 220 may overlap with a virtual center line penetrating the center of the first semiconductor chip 110. However, the position of the dummy chip 220 may be adjusted according to the position of the portion of the first semiconductor chip 110 where heat is generated the most.

The dummy chip 220 may be disposed on one side of the chip stack CS. The dummy chip 220 may be disposed at the same height as the chip stack CS. If there are two or more chip stacks CS, the dummy chip 220 may be disposed between the chip stacks CS. For example, the chip stacks CS may be disposed on both sides of the dummy chip 220.

Each of the dummy chips 220 may be disposed at a height corresponding to a height of each semiconductor chip of the chip stack CS. For example, the semiconductor chip and the dummy chip may be provided in the same molding layer as each other. The semiconductor chip and the dummy chip provided in the same molding layer may have a thickness corresponding to the thickness of the corresponding molding layer.

An area of first semiconductor chip 110 that is covered by the dummy chip 220 may be smaller than a total area of the first semiconductor chip 110. For example, about 30% to about 40% of the area of the first semiconductor chip 100 may be covered. The “area” as used herein may be defined as an area on a plane that is parallel to a surface of the package substrate 150. However, the size of the dummy chip 220 is not limited thereto.

As illustrated in FIG. 1, the first dummy chip 222 and the second dummy chip 221 may have the same shape as each other. However, the present inventive concept is not limited thereto, and there may be more layers such as a third dummy chip, or layers may have different shapes from each other.

Hereinafter, a manufacturing method for the semiconductor package according to embodiments of the present inventive concept will be described. The like or similar components as those of the semiconductor package 1 according to some embodiments of the present inventive concept described above will be given the same reference numerals, and redundant descriptions may be omitted or briefly discussed.

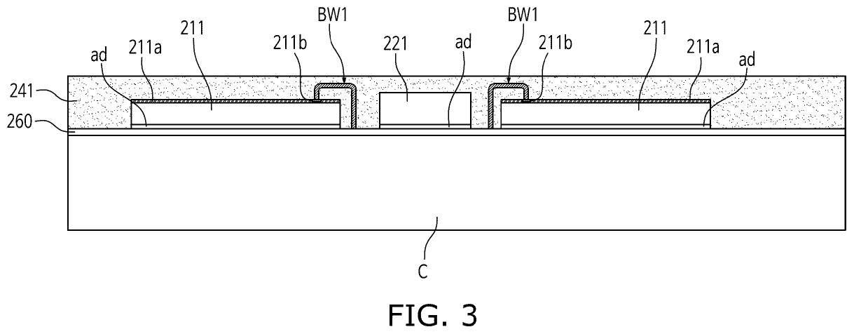

FIGS. 3 to 11 are diagrams illustrating a process of manufacturing a semiconductor package according to embodiments of the present inventive concept.

Referring to FIG. 3, a manufacturing method for the semiconductor package according to embodiments of the present inventive concept may include disposing the metal layer 260 on a carrier substrate C.

An upper memory chip 211 may be disposed on the metal layer 260. There may be two or more upper memory chips 211. The upper memory chip 211 may be disposed with its active surface 211a facing upward. That is, the upper memory chip 211 may have the active surface 211a disposed opposite to the carrier substrate C.

An adhesive layer ad may be attached to an opposite surface of the active surface 211a of the upper memory chip 211. The upper memory chip 211 may be adhered to the metal layer 260 by the adhesive layer ad.

The upper dummy chip 221 may be disposed on the metal layer 260. The upper dummy chip 221 may be disposed on one side of the upper memory chip 211. The upper dummy chip 221 may be adhered to the metal layer 260 through the adhesive layer ad.

A first bonding wire BW1 may be provided to electrically connect the upper memory chip 211 and the metal layer 260 to each other. The first bonding wire BW1 may be connected to the chip pad 211b, of the upper memory chip 211, and the metal layer 260. Before a molding process of forming the upper molding layer 241, the first bonding wire BW1 may be fixed to the upper memory chip 211 and the metal layer 260 so as to prevent a sweeping phenomenon.

The first bonding wire BW1 may be extended upward from the metal layer 260, bent, and extended downward toward the chip pad 211b. The molding process may be performed after the first bonding wire BW1 connects between the metal layer 260 and the upper memory chip 211.

The upper molding layer 241 may be formed to seal the upper memory chip 211 and the first bonding wire BW1. Because the first bonding wire BW1 is fixed to the metal layer 260 and the upper memory chip 211, deformation of the first bonding wire BW1 can be prevented even when the material for forming the upper molding layer 241 is injected.

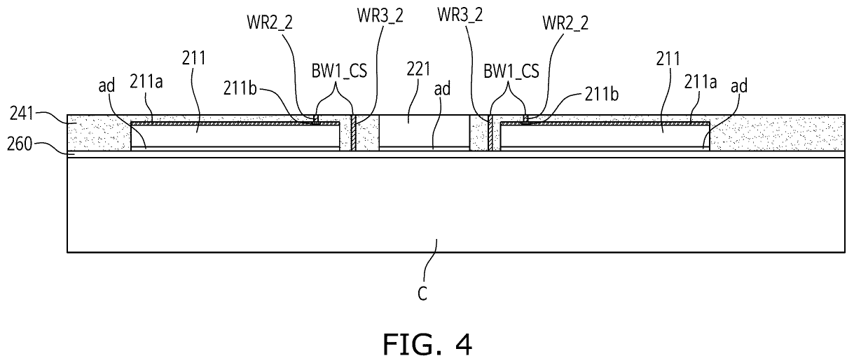

Referring to FIG. 4, the upper molding layer 241 and a portion of the first bonding wire BW1, which is buried in the upper molding layer 241, may be removed by grinding. The grinding may be performed by a grinding wheel or chemical mechanical polishing (CMP), etc. However, the grinding method is not limited to the above, and may be performed in various ways.

Portions of the wire may be removed through the grinding, except for the second portion WR3_2 of the third wire WR3, which is a portion extending upward from the metal layer 260, and the second portion WR2_2 of the second wire WR2, which is a portion extending upward from the upper memory chip 211. That is, the second portion WR3_2 of the third wire WR3 and the second portion WR2_2 of the second wire WR2 may remain. The portion of the upper molding layer 241 may be removed by grinding, exposing a cut surface BW1_CS of the first bonding wire BW1. That is, the cut surface BW1_CS of the first bonding wire BW1 may be exposed to the outside of the upper molding layer 241.

In addition, the upper dummy chip 221 may be exposed to the outside of the upper molding layer 241 by grinding. A portion of the upper dummy chip 221 may be removed by grinding. For example, the upper molding layer 241 positioned on the upper side of the upper dummy chip 221 may be removed.

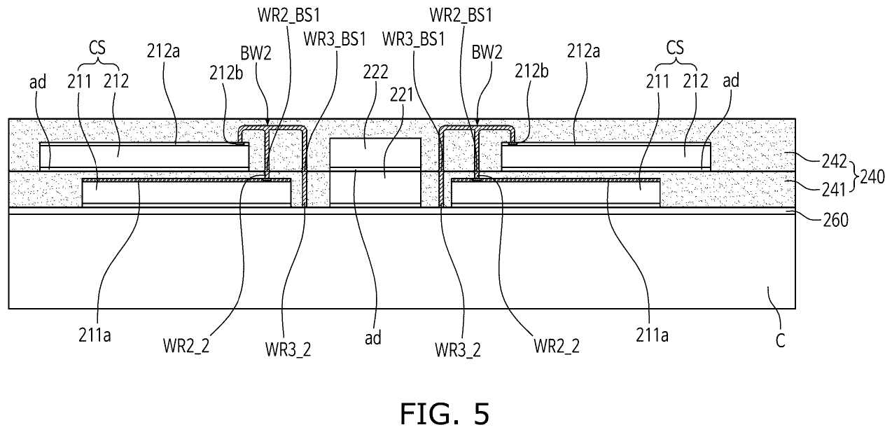

Referring to FIG. 5, a lower memory chip 212 may be disposed on the upper molding layer 241. The lower memory chip 212 may be disposed to be offset stacked with the upper memory chip 211. For example, the lower memory chip 212 may be disposed to overlap a portion of the upper memory chip 211. The lower memory chip 212 may be disposed such that the lower memory chip 212 might not interfere with the second portion WR2_2 of the second wire WR2 that is connected to the upper memory chip 211. For example, the lower memory chip 212 might not overlap the second portion WR2_2 of the second wire WR2. The lower memory chip 212 may be adhered to the upper molding layer 241 through an adhesive layer ad.

The expressions “upper” and “lower” are used herein for easier understanding of the aspects based on the final semiconductor package structure rather than the process stage, and they do not mean any physical positions in specific process stages. In addition, the expressions “upper” and “lower” are not intended to mean that a certain configuration is above or below another configuration, but rather, the expressions “upper” and “lower” are used to simply refer to some configurations belonging to a stacked structure.

A lower dummy chip 222 may be disposed on the upper dummy chip 221 that is exposed to the outside of the upper molding layer 241. The lower dummy chip 222 may be disposed to be aligned with the upper dummy chip 221. In addition, the lower dummy chip 222 may be disposed to overlap at least a portion of the upper dummy chip 221.

A second bonding wire BW2 may connect the cut surface BW1_CS of the first bonding wire BW1 that are exposed to the outside of the upper molding layer 241 to the chip pad 212b of the lower memory chip 212. Because two cut surfaces BW1_CS of the first bonding wire BW1 formed, the second bonding wire BW2 may be connected at a total of three locations including the chip pad 212b of the lower memory chip 212.

Before the molding process of forming the lower molding layer 242, the second bonding wire BW2 may be fixed to the cut surface BW1_CS of the first bonding wire BW1 and the chip pad 212b of the lower memory chip 212 so as to prevent a sweeping phenomenon.

For example, the second bonding wire BW2 may include a first wire that connects one of the cut surfaces BW1_CS of the first bonding wire BW1 to the chip pad 212b of the lower memory chip 212, and a second wire that connects the other one of the cut surfaces BW1_CS of the first bonding wire BW1 to the chip pad 212b of the lower memory chip 212. For example, the second wire may connect to the first wire. Alternatively, the second bonding wire BW2 may include a first wire that connects the cut surfaces BW1_CS of the first bonding wire BW1 to each other, and a second wire that extends from the first wire and connects to the chip pad 212b of the lower memory chip 212. In addition, the structure of the second bonding wire BW2 is not limited to the above and may be variously configured.

The second bonding wire BW2 may be extended upward from the cut surface BW1_CS of the first bonding wire BW1, bent in a direction in which the lower memory chip 212 is offset, and extended downward toward the chip pad 212b of the lower memory chip 212. For example, the second bonding wire BW2 may be bent in the direction of the lower memory chip 212.

The lower molding layer 242 may be formed to seal the lower memory chip 212 and the second bonding wire BW2. Because the second bonding wire BW2 is fixed to the cut surface BW1_CS of the first bonding wire BW1 and the lower memory chip 212, deformation of the second bonding wire BW2 can be prevented even when the material for forming the lower molding layer 242 is injected.

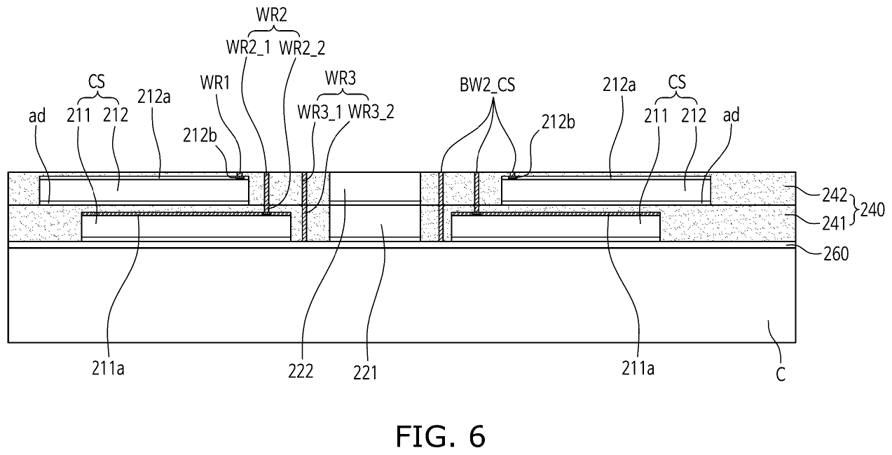

Referring to FIG. 6, the lower molding layer 242 and a portion of the second bonding wire BW2 that is buried by the lower molding layer 242 may be removed by grinding. The grinding may be performed by a grinding wheel or chemical mechanical polishing (CMP), etc. However, the grinding method is not limited to the above, and may be performed in various ways.

Portions of the second bonding wire BW2 may be removed through the grinding, except for the portion of the second bonding wire BW2 that forms the first portion WR3_1 of the third wire WR3, which is a portion extending upward from the second portion WR3_2 of the third wire WR3, the portion of the second bonding wire BW2 that forms the first wire WR1, which extends from chip pad 212b of the lower memory chip 212, and the portion of the second bonding wire BW2 that forms the first portion WR2_1 of the second wire WR2, which is a portion extending upward from the second portion WR2_2 of the second wire WR2. That is, the first portion WR3_1 of the third wire WR3, the first portion WR2_1 of the second wire WR2, and the first wire WR1 may remain. The portion of the lower molding layer 242 may be removed by grinding, exposing a cut surface BW2_CS of the second bonding wire BW2. That is, the cut surface BW2_CS of the second bonding wire BW2 may be exposed to the outside of the lower molding layer 242.

In addition, the lower dummy chip 222 may be exposed to the outside of the lower molding layer 242 by grinding. A portion of the lower dummy chip 222 may be removed by grinding. For example, the lower molding layer 242 positioned on the upper side of the lower dummy chip 222 may be removed.

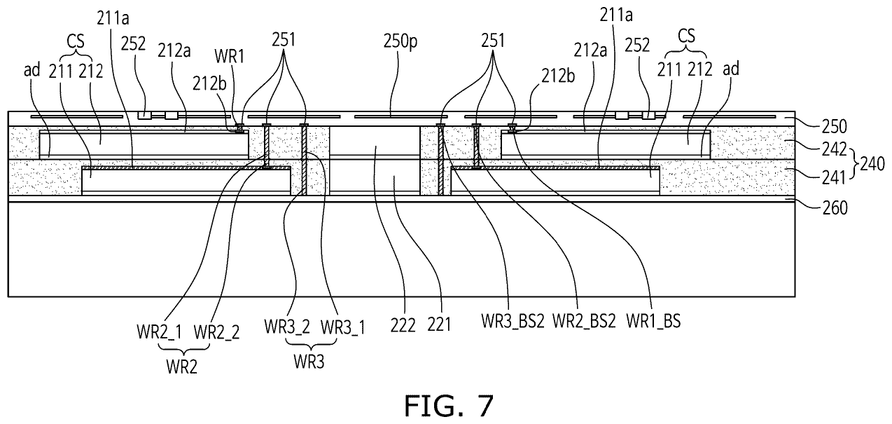

Referring to FIG. 7, the redistribution layer 250 may be disposed on the lower molding layer 242. The redistribution layer 250 may be electrically connected to the first wire WR1, the second portion WR2_2 of the second wire WR2, and the second portion WR3_2 of the third wire WR3. The upper pad 251 of the redistribution layer 250 may be disposed to be electrically connected to the cut surface BW2_CS of the second bonding wire BW2.

Each of the first portion WR3_1 of the third wire WR3, the first portion WR2_1 of the second wire WR2, and the first wire WR1 may be bonded to a corresponding upper pad 251 of the redistribution layer 250. In this process, the bonding surface WR3_BS2 of the third wire WR3, the bonding surface WR2_BS2 of the second wire WR2, and the bonding surface WR1_BS of the first wire WR1 may be formed.

The redistribution layer 250 may be disposed such that the upper pad 251 is positioned to face the lower molding layer 242. That is, the lower pad 252 may be disposed facing upward.

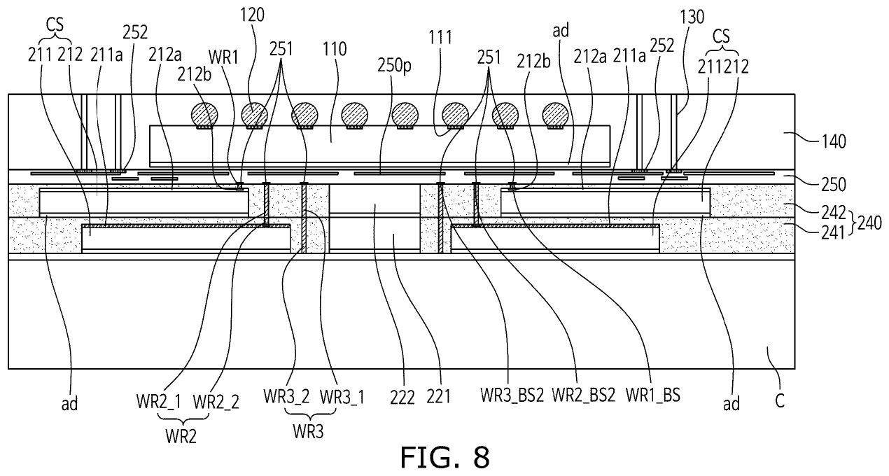

Referring to FIG. 8, a logic chip 110 may be disposed on the redistribution layer 250. The logic chip 110 may be adhered to the redistribution layer 250 by an adhesive layer ad. The logic chip 110 may be disposed such that the central portion of the logic chip 110 is positioned on the dummy chips 221 and 222. The adhesive layer ad may be disposed on a surface of the logic chip 110 that is opposite to the active surface of the logic chip 110. The logic chip 110 may be disposed with the active surface facing upward.

With a manufacturing method for the semiconductor package according to embodiments of the present inventive concept, one system in package (SiP) can be manufactured without having a separate connection terminal disposed in the redistribution layer 250. In addition, the thickness of the semiconductor package can be reduced and the wiring length can also be shortened, thereby improving electrical performance. For example, the input and output signal speed of the electromagnetic wave shielding function in the metal layer 260 can be increased. In addition, heat generated in the semiconductor package can be easily dissipated.

With the manufacturing method for the semiconductor package according to embodiments of the present inventive concept, the upper semiconductor package 20 and the lower semiconductor package 10 may be sequentially stacked without being separately manufactured, thereby reducing the manufacturing time of the semiconductor package.

The chip terminal 120 may be disposed on the active surface of the logic chip 110. That is, the logic chip 110 may be disposed with the chip terminal 120 facing upward. In this case, a bumping process of forming the chip terminal 120 of the logic chip 110 may have been completed.

The connection terminal 130 may be disposed on one side of the logic chip 110. The connection terminals 130 may be disposed adjacent to sides of the logic chip 110. The connection terminal 130 may be a metal post. For example, the connection terminal 130 may be a copper (Cu) post. However, the present inventive concept is not limited thereto, and for example, a bonding wire may be used.

The connection terminal 130 may be connected to the lower pad 252 of the redistribution layer 250. The connection terminal 130 may extend longer than the thickness of the logic chip 110. For example, the connection terminal 130 may have a length that is larger than the thickness of the logic chip 110. The connection terminal 130 may electrically connect elements, which are electrically connected to the redistribution layer 250, to an external element.

A logic chip molding layer 140 may be formed on the redistribution layer 250 to cover the logic chip 110 and the connection terminal 130. The logic chip molding layer 140 may be formed to cover the chip terminal 120. The logic chip molding layer 140 may cover the connection terminal 130 from exposure. However, the present inventive concept is not limited thereto, and any variations are possible as long as the logic chip molding layer 140 can cover the logic chip 110. For example, the logic chip molding layer 140 may be formed such that it may expose at least a portion of the chip terminal 120, and may be formed such that it may expose at least a portion of the connection terminal 130.

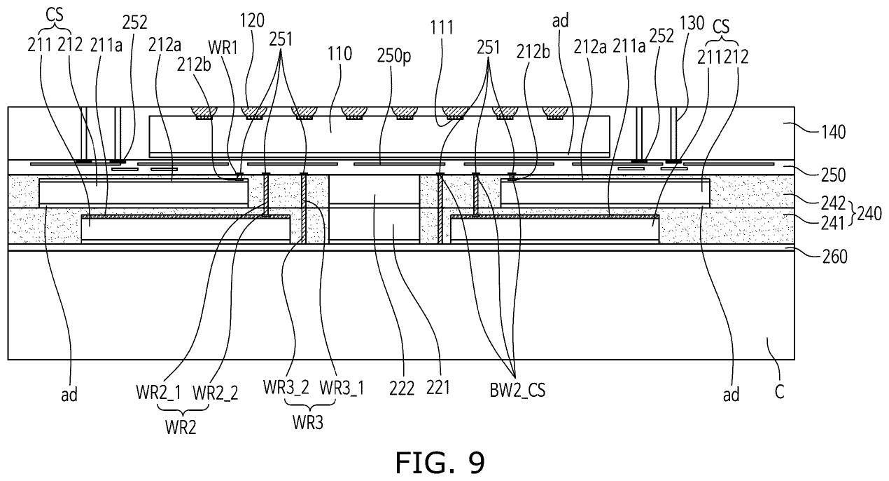

Referring to FIG. 9, at least a portion of the logic chip molding layer 140 may be ground to expose a portion of the chip terminal 120 and a portion of the connection terminal 130. The portion of the chip terminal 120 and the portion of the connection terminal 130 may be ground and removed together, while the at least the portion of the logic chip molding layer 140 is ground. The grinding may be performed by a grinding wheel or chemical mechanical polishing (CMP), etc. However, the grinding method is not limited to the above, and may be performed in various ways.

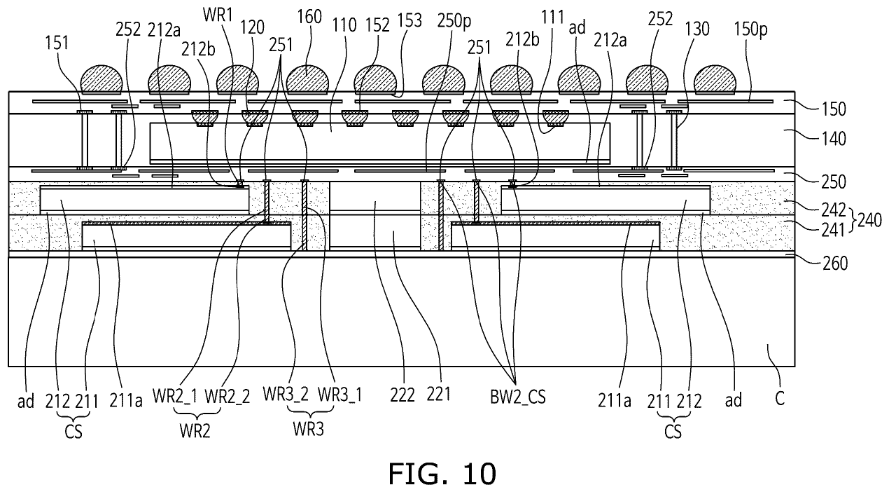

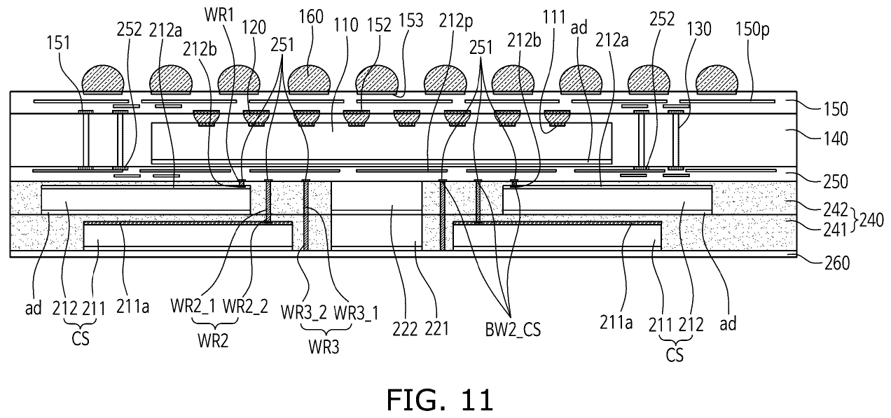

Referring to FIGS. 10 and 11, the package substrate 150 may be disposed to be electrically connected the chip terminal 120 and the connection terminal 130, which are exposed to the outside by grinding.

The package substrate 150 may be disposed such that the upper pads 151 and 152 are electrically connected to the chip terminal 120 and the connection terminal 130. Specifically, the first upper pad 151 may be connected to the chip terminal 120, and the second upper pad 152 may be connected to the connection terminal 130.

The external terminal 160 may be disposed on the package substrate 150 such that an element electrically connected to the redistribution layer 250 may be connected to an external element through the external terminal 160. The conductive pattern 150p may be formed to electrically connect the upper pads 151 and 152 and the external pad 153 of the package substrate 150 to each other. The external terminal 160 may be disposed on the external pad 153.

The carrier substrate C may be removed so that the metal layer 260 is exposed. The semiconductor package 1 may be turned over and mounted on a substrate such as a PCB.

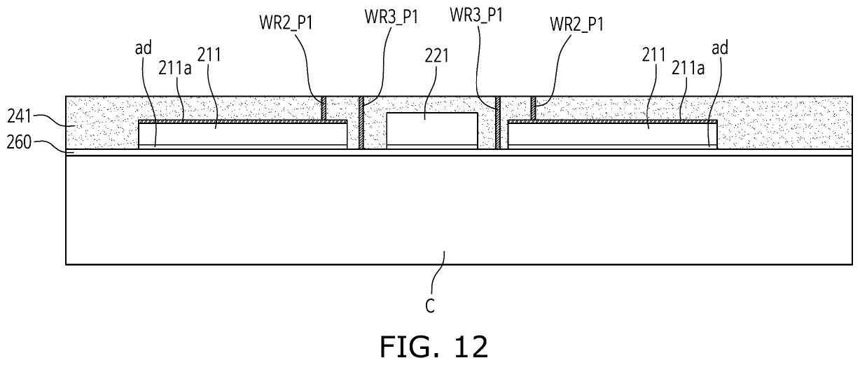

FIGS. 12 to 16 are diagrams illustrating a process of manufacturing a semiconductor package according to embodiments of the present inventive concept.

The manufacturing method for the semiconductor package 1 illustrated in FIGS. 12 to 16 relates to the method for manufacturing the upper semiconductor package 20, and may be equally applicable to the method for manufacturing the lower semiconductor package 10 (refer to FIG. 10), which will not be redundantly described in detail.

Referring to FIG. 12, a manufacturing method for the semiconductor package according to embodiments of the present inventive concept may be initiated by disposing the upper memory chip 211 and the upper dummy chip 221 on the carrier substrate C.

A first section WR3 P1 of the third wire WR3 may be vertically disposed on the metal layer 260. The first section WR3_P1 of the third wire WR3 may be formed to be longer than the thickness of the upper memory chip 211. For example, the first section WR3_P1 of the third wire WR3 may have a length corresponding to or similar to a thickness of the upper memory chip 211.

A first section WR2_P1 of the second wire WR2 may be vertically disposed on the upper memory chip 211. An upper end of the first section WR2_P1 of the second wire WR2 may be positioned at a height similar to an upper end of the first section WR3_P1 of the third wire WR3. The upper end of the first section WR2_P1 of the second wire WR2 may be substantially coplanar with the upper end of the first section WR3_P1 of the third wire WR3. Even if the upper end of the first section WR2_P1 of the second wire WR2 and the upper end of the first section WR3_P1 of the third wire WR3 are formed at different heights from each other, they may be formed to have the same height by a grinding process, which is to be described below.

The first section WR2_P1 of the second wire WR2 may be fixed to the chip pad 211b of the upper memory chip 211. In addition, the first section WR3_P1 of the third wire WR3 may be fixed to the metal layer 260. The first section WR2_P1 of the second wire WR2 and the first section WR3_P1 of the third wire WR3 may extend upward from the chip pad 211b and the metal layer 260, respectively.

The upper molding layer 241 may be formed on the metal layer 260. The upper molding layer 241 may cover the upper memory chip 211 and the upper dummy chip 221. The upper memory chip 211 and the upper dummy chip 221 may be buried and sealed by the upper molding layer 241.

The upper molding layer 241 may cover at least a portion of the first section WR2_P1 of the second wire WR2 and at least a portion of the first section WR3_P1 of the third wire WR3. The length of each of the first section WR2_P1 of the second wire WR2 and the first section WR3 P1 of the third wire WR3 may correspond to or be similar to the thickness of the upper molding layer 241. For example, the length of the first section WR2_P1 of the second wire WR2 may correspond to or be similar to a thickness of a portion of the upper molding layer 241 that overlaps a lower surface of the upper memory chip 211 in vertical direction, and the length of the first section WR3_P1 of the third wire WR3 may correspond to or be similar to a thickness of the upper molding layer 241 that is from the bottom surface of the upper molding layer 241 to the top surface of the upper molding layer 241.

Because the first section WR2_P1 of the second wire WR2 and the first section WR3_P1 of the third wire WR3 are extended in units of sections, it is less likely that the sweeping phenomenon would occur than when each of the second wire WR2 and the third wire WR3 are integrally formed. Because the first section WR2_P1 of the second wire WR2 and the first section WR3_P1 of the third wire WR3 have a height corresponding to or similar to the thickness of the upper memory chip 211, deformation can be prevented even when a material for forming the upper molding layer 241 is injected. In other words, the external force applied to the first section WR2_P1 of the second wire WR2 and the first section WR3_P1 of the third wire WR3 while the material for forming the upper molding layer 241 is injected into the upper memory chip 211 may be alleviated.

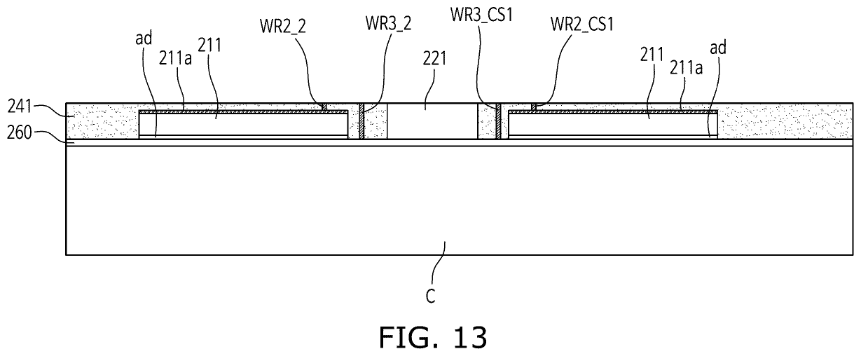

Referring to FIG. 13, a portion of the upper molding layer 241 may be ground so that a portion of the first section WR2_P1 of the second wire WR2 and a portion of the first section WR3_P1 of the third wire WR3 are exposed to the outside of the upper molding layer 241.

The portion of the first section WR2_P1 of the second wire WR2 and the portion of the first section WR3_P1 of the third wire WR3 may be removed. A cut surface WR2_CS1 of the first section WR2 P1 of the second wire WR2 and a cut surface WR3_CS1 of the first section WR3_P1 of the third wire WR3 may be exposed to the outside of the upper molding layer 241. The remaining portion of the first section WR2_P1 of the second wire WR2 and the remaining portion of the first section WR3_P1 of the third wire WR3 may correspond to the second portion WR2_2 of the second wire WR2 and the second portion WR3_2 of the third wire WR3, respectively.

The grinding process illustrated in FIG. 13 may be omitted if the first section WR2_P1 of the second wire WR2 and the first section WR3_P1 of the third wire WR3 are not completely buried by the upper molding layer 241 and buried to the extent such that the upper end of each section is exposed. That is, even when the cut surfaces WR2_CS1 and WR3_CS1 of the first section WR2_P1 of the second wire WR2 and the first section WR3_P1 of the third wire WR3 are not formed, the grinding process may be omitted if a portion of the first section WR2_P1 of the second wire WR2 and a portion of the first section WR3_P1 of the third wire WR3 are exposed from the upper molding layer 241.

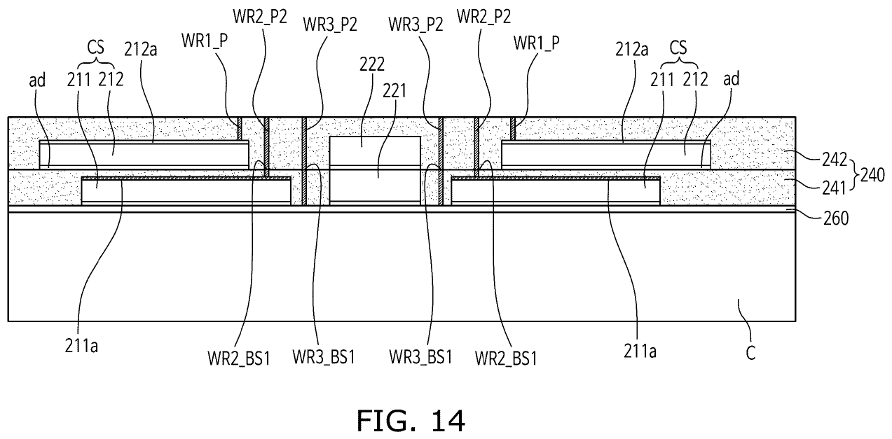

Referring to FIGS. 13 and 14, the lower memory chip 212 and the lower dummy chip 222 may be disposed on the lower molding layer 242.

A second section WR3_P2 of the third wire WR3 may be disposed on the metal layer 260. The second section WR3_P2 of the third wire WR3 may be formed to be longer than the thickness of the lower memory chip 212. The second section WR3_P2 of the third wire WR3 may have a length corresponding to or similar to the thickness of the lower memory chip 212.

A section WR1_P of the first wire WR1 may be disposed on the lower memory chip 212. A second section WR2_P2 of the second wire WR2 may be disposed on the cut surface WR2_CS1 of the first section WR2 P1 of the second wire WR2. Likewise, the second section WR3_P2 of the third wire WR3 may be disposed on the cut surface WR3_CS1 of the first section WR3_P1 of the third wire WR3.

The first section WR2_P1 of the second wire WR2 and the second section WR2_P2 of the second wire WR2 may be bonded to each other. The second wire WR2 may include the bonding surface WR2_BS1 that is formed as the first and second sections WR2_P1 and WR2_P2 are bonded to each other.

The first section WR3_P1 of the third wire WR3 and the second section WR3_P2 of the third wire WR3 may be bonded to each other. The third wire WR3 may include the bonding surface WR3_BS1 that is formed as the first and second sections WR3_P1 and WR3_P2 are bonded to each other. A bonding surface may be formed as the section WR1_P of the first wire WR1 is bonded to the chip pad 212b of the lower semiconductor chip 212.

An upper end of the second section WR2_P2 of the second wire WR2 may be positioned at a height that is similar to each of an upper end of the second section WR3_P2 of the third wire WR3 and an upper end of the section WR1_P of the first wire WR1. The upper end of the section WR1_P of the first wire WR1, the upper end of the second section WR2_P2 of the second wire WR2, and the upper end of the second section WR3_P2 of the third wire WR3 may be substantially coplanar. Even if the sections are formed with different heights, the sections may be formed to have the same height by the grinding process to be described below.

The section WR1_P of the first wire WR1 may be fixed to the chip pad 212b of the lower memory chip 212. The second section WR2_P2 of the second wire WR2 may be fixed to the cut surface WR2_CS1 of the first section WR2_P1 of the second wire WR2. In addition, the second section WR3_P2 of the third wire WR3 may be fixed to the cut surface WR3_CS1 of the first section WR3_P1 of the third wire WR3. The first section WR2_P1 of the second wire WR2 and the first section WR3_P1 of the third wire WR3 may extend upward from the chip pad 211b and the metal layer 260, respectively.

The lower molding layer 242 may be formed on the upper molding layer 241. The lower molding layer 242 may cover the lower memory chip 212 and the lower dummy chip 222. The lower memory chip 212 and the lower dummy chip 222 may be buried and sealed in the lower molding layer 242.

The lower molding layer 242 may cover at least a portion of the section WR1 P of the first wire WR1, at least a portion of the second section WR2_P2 of the second wire WR2, and at least a portion of the second section WR3_P2 of the third wire WR3. The length of each of the first section WR2 Pl of the second wire WR2 and the first section WR3_P1 of the third wire WR3 may correspond to or be similar to the thickness of the upper molding layer 241.

Because the section WR1_P of the first wire WR1, the second section WR2_P2 of the second wire WR2, and the second section WR3_P2 of the third wire WR3 extend in units of sections, it is less likely that the sweeping phenomenon would occur than when each of the first wireWR1, the second wire WR2, and the third wire WR3 is integrally formed. Because each of the second section WR2_P2 of the second wire WR2 and the second section WR3_P2 of the third wire WR3 has a height corresponding to or similar to the thickness of the lower memory chip 212, deformation can be prevented even when a material for forming the lower molding layer 242 is injected. In other words, the external force that is applied to the second section WR2_P2 of the second wire WR2 and the second section WR3_P2 of the third wire WR3 while the material for forming the lower molding layer 242 is injected into the lower memory chip 212 may be alleviated.

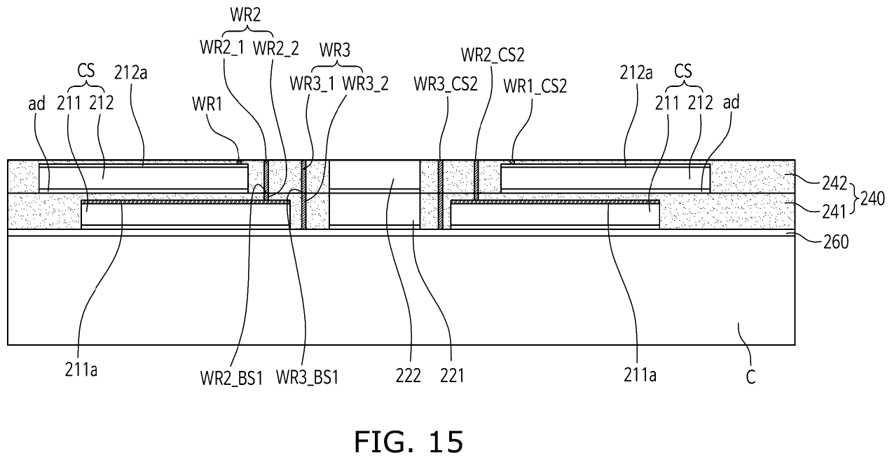

Referring to FIGS. 14 and 15, a portion of the lower molding layer 242 may be ground to expose a portion of the section WR1_P of the first wire WR1, a portion of the second section WR2 P2 of the second wire WR2, and a portion of the second section WR3_P2 of the third wire WR3.

The portion of the section WR1_P of the first wire WR1, the portion of the second section WR2_P2 of the second wire WR2, and the portion of the second section WR3_P2 of the third wire WR3 may be removed. A cut surface WR1_CS of the section WR1_P of the first wire WR1, a cut surface WR2_CS2 of the second section WR2 P2 of the second wire WR2, and a cut surface WR3_CS2 of the second section WR3_P2 of the third wire WR3 may be exposed to the outside of the lower molding layer 242. The remaining portion of the section WR1_P of the first wire WR1 may be the first wire WR1. In addition, the remaining portion of the second section WR2_P2 of the second wire WR2 and the remaining portion of the second section WR3_P2 of the third wire WR3 may be the first portion WR2_1 of the second wire WR2 and the first portion WR3_1 of the third wire WR3, respectively.

The grinding process illustrated in FIG. 15 may be omitted if the section WR1_P of the first wire WR1, the second section WR2_P2 of the second wire WR2, and the second section WR3_P2 of the third wire WR3 are not completely buried by the lower molding layer 242 and buried to the extent such that the upper end of each section WR1_P, WR2_P2, and WR3_P2 is exposed to the outside of the lower molding layer 242. That is, even when the cut surfaces WR1_CS2, WR2_CS2, and WR3_CS2 of the section WR1_P of the first wire WR1, the second section WR2_P2 of the second wire WR2, and the second section WR3_P2 of the third wire WR3 are not formed, the grinding process may be omitted if a portion of the section WR1_P of the first wire WR1, a portion of the second section WR2_P2 of the second wire WR2, and a portion of the second section WR3_P2 of the third wire WR3 are exposed to the outside of the lower molding layer 242.

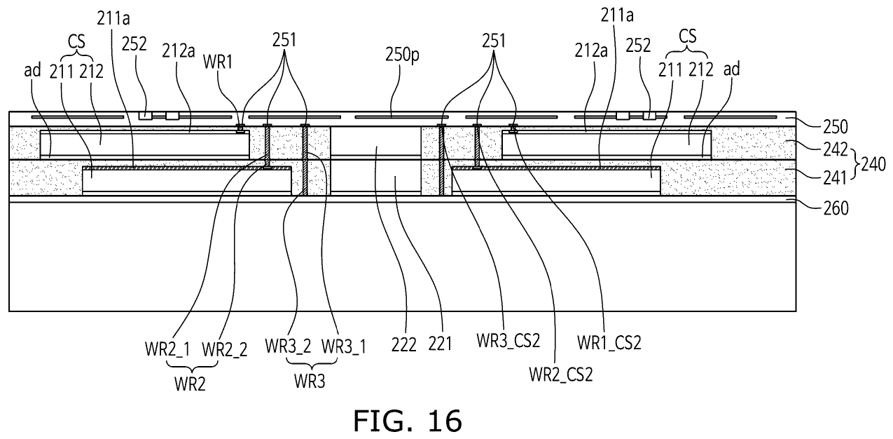

Referring to FIG. 16, the redistribution layer 250 may be disposed on the lower molding layer 242.

The redistribution layer 250 may be electrically connected to the first wire WR1, the first portion WR2_1 of the second wire WR2, and the first portion WR3_1 of the third wire WR3, respectively. Upper pads 251 of the redistribution layer 250 may be electrically connected to the cut surface WR1_CS of the section WR1_P of the first wire WR1, the cut surface WR2 CS2 of the second section WR2_P2 of the second wire WR2, and the cut surface WR3_CS2 of the second section WR3_P2 of the third wire WR3, respectively, which are exposed to the outside of the lower molding layer 242.

Each of the first portion WR3_1 of the third wire WR3, the first portion WR2_1 of the second wire WR2, and the first wire WR1 may be bonded to a corresponding upper pad 251 of the redistribution layer 250. In this process, the bonding surface WR3_BS2 of the third wire WR3, the bonding surface WR2_BS2 of the second wire WR2, and the bonding surface WR1_BS of the first wire WR1 may be formed.

Hereinafter, embodiments of the present inventive concept that may be different from the semiconductor package 1 will be described. The same or similar elements and configurations will be given the same reference numerals, and redundant descriptions thereof may be omitted or briefly discussed.

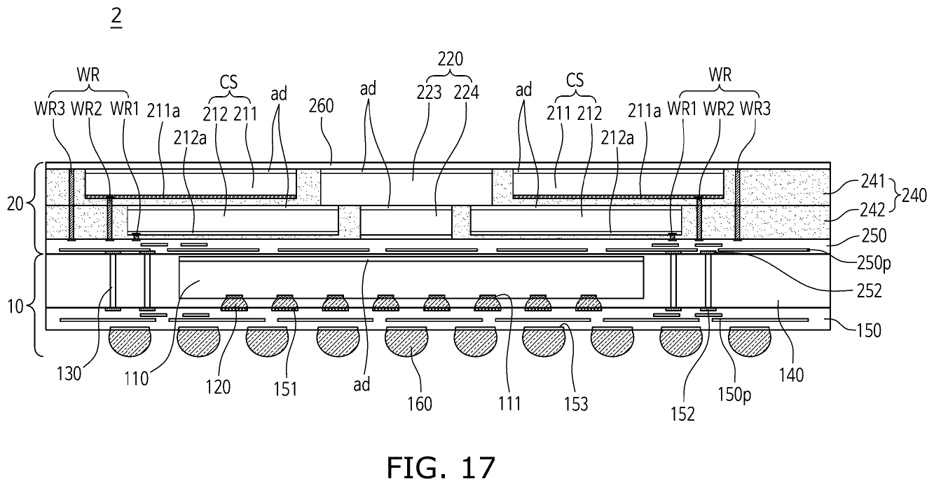

FIG. 17 is a diagram illustrating a semiconductor package according to embodiments of the present inventive concept.

Referring to FIG. 17, a semiconductor package 2 according to embodiments of the present inventive concept may include the lower semiconductor package 10 and the upper semiconductor package 20.

The upper semiconductor package 20 may include the redistribution layer 250 and one or more chip stacks CS disposed on the redistribution layer 250. The chip stack CS may include the second semiconductor chip 212 and the third semiconductor chip 211.

The second semiconductor chip 212 and the third semiconductor chip 211 may be disposed in an offset stack structure. For example, the second semiconductor chip 212 and the third semiconductor chip 211 may be stacked to be offset to one side, which may be in a cascade form. For example, the third semiconductor chip 211 may be misaligned with the second semiconductor chip 212. As another example, the second semiconductor chip 212 and the third semiconductor chip 211 may form a stepped or staircase structure.

The offset stack directions of the chip stacks CS may be different from each other. The offset stack directions of each chip stack CS may vary according to the arrangement of the upper pad 251 of the redistribution layer 250 and the arrangement of each chip pad of the chip stack

CS. FIG. 17 illustrates an example in which each chip stack CS is offset stacked in a direction away from the center of the semiconductor package 2, but the present inventive concept is not limited thereto. For example, in each of the chip stacks CS, the third semiconductor chip 211 may be further away from the center of the semiconductor package 2 than the second semiconductor chip 212.

The semiconductor package 2 may include the dummy chip 220 for dissipating heat that may be generated from the first semiconductor chip 110. The dummy chip 220 may be provided in the upper semiconductor package 20.

The dummy chip 220 may include the first dummy chip 224 and a second dummy chip 223. The first dummy chip 224 may be disposed on the redistribution layer 250, and the second dummy chip 223 may be disposed on the first dummy chip 224. The metal layer 260 may be disposed on the upper side of the second dummy chip 223. The second dummy chip 223 may be adhered to the metal layer 260 through the adhesive layer ad.

The first dummy chip 224 and the second dummy chip 223 may have different sizes from each other, as illustrated in FIG. 17. The second dummy chip 223 may have a size that is greater than a size of the first dummy chip 224. In addition, the second dummy chip 223 may have a size that is smaller than a size of the first dummy chip 224. However, the present inventive concept is not limited thereto, and there may be more layers such as a third dummy chip, or layers may have different shapes from each other.

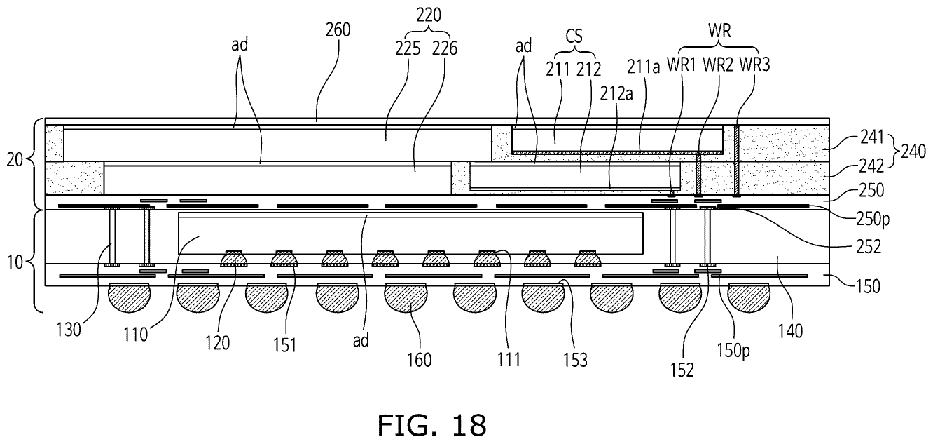

FIG. 18 is a diagram illustrating a semiconductor package according to embodiments of the present inventive concept.

Referring to FIG. 18, a semiconductor package 3 according to embodiments of the present inventive concept may include the lower semiconductor package 10 and the upper semiconductor package 20.

The upper semiconductor package 20 may include the redistribution layer 250 and one chip stack CS disposed on the redistribution layer 250. The chip stack CS may include the second semiconductor chip 212 and the third semiconductor chip 211.

The second semiconductor chip 212 and the third semiconductor chip 211 may be disposed in an offset stack structure. For example, the second semiconductor chip 212 and the third semiconductor chip 211 may be stacked offset to one side, which may be in a cascade form. For example, the third semiconductor chip 211 may be misaligned with the second semiconductor chip 212. As another example, the second semiconductor chip 212 and the third semiconductor chip 211 may form a stepped or staircase structure.

The offset stack direction of the chip stack CS illustrated in FIG. 18 may be a direction in which the third semiconductor chip 211 is positioned on the upper side of the second semiconductor chip 212 and away from the dummy chip 220. However, the offset stack direction of the chip stack CS may vary according to the arrangement of the upper pad 251 of the redistribution layer 250 and the arrangement of the chip pads of the chip stack CS. FIG. 1 illustrates an example in which each chip stack CS is offset stacked in a direction away from the center of the semiconductor package 2, but the present inventive concept is not limited thereto.

The semiconductor package 2 may include the dummy chip 220 for dissipating heat that may be generated from the first semiconductor chip 110. The dummy chip 220 may be provided in the upper semiconductor package 20.

The dummy chip 220 may include the first dummy chip 226 and a second dummy chip 225. The first dummy chip 226 may be disposed on the redistribution layer 250, and the second dummy chip 225 may be disposed on the first dummy chip 226. The metal layer 260 may be disposed on the upper side of the second dummy chip 225. The second dummy chip 225 may be adhered to the metal layer 260 through the adhesive layer ad.

The first dummy chip 226 and the second dummy chip 225 may have different sizes from each other, as illustrated in FIG. 18. The second dummy chip 225 may have a size that is greater than a size of the first dummy chip 226. In addition, the second dummy chip 225 may have a size that is smaller than a size of the first dummy chip 226. However, the present inventive concept is not limited thereto, and there may be more layers such as a third dummy chip, or layers may have different shapes from each other.

The dummy chip 220 may have various sizes according to heat generation of the first semiconductor chip 110. For example, if an amount of heat generated by the first semiconductor chip 110 is increased, the size of the dummy chip 220 may be increased. By increasing the size of the dummy chip 220, the amount of heat, which may be generated from the first semiconductor chip 110, that may be conducted to the dummy chip 220 may be increased.

The dummy chip 220 may be disposed on one side of the chip stack CS. The dummy chip 220 may be disposed at substantially the same height as the chip stack CS. Even in this case, the dummy chip 220 may be positioned on the central portion of the first semiconductor chip 110. However, the position of the dummy chip 220 may be adjusted according to the position of the portion of the first semiconductor chip 110 that is generating the most heat.

For example, the first dummy chip 226 and the second dummy chip 225 may be stacked on each other in a direction that is substantially perpendicular to an upper surface of the redistribution layer 250. In this case, the first dummy chip 226 and the second dummy chip 225 may be disposed to at least partially overlap each other. The first dummy chip 226 and the second dummy chip 225 may be positioned on the central portion of the first semiconductor chip 110. For example, at least a portion of the dummy chip 220 may overlap with a virtual center line penetrating the center of the first semiconductor chip 110.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package, comprising:
a redistribution layer;
a lower semiconductor chip disposed on the redistribution layer;
an upper semiconductor chip stacked on the lower semiconductor chip;
a lower molding layer having a thickness corresponding to a distance between an upper surface of the redistribution layer and an upper surface of the lower semiconductor chip, and covering the lower semiconductor chip;
an upper molding layer having a thickness corresponding to a distance between an upper surface of the lower molding layer and an upper surface of the upper semiconductor chip, and covering the upper semiconductor chip;
a first wire connecting the lower semiconductor chip and the redistribution layer to each other in a vertical direction; and
a second wire connecting the upper semiconductor chip and the redistribution layer to each other in the vertical direction,
wherein the second wire includes a first portion, a second portion, and a bonding surface, wherein the first portion is disposed in the lower molding layer, wherein the second portion is disposed in the upper molding layer, and wherein the first portion of the second wire and the second portion of the second wire are bonded to each other at the bonding surface.

2. The semiconductor package according to claim 1, wherein
the first wire includes a bonding surface at which the first wire is connected to the redistribution layer,
the second wire further includes a bonding surface at which the first portion of the second wire is connected to the redistribution layer, and
the bonding surface, at which the first wire is connected to the redistribution layer, and the bonding surface, at which the first portion of the second wire is connected to the redistribution layer, are positioned on a same plane.

3. The semiconductor package according to claim 2, further comprising:
a metal layer disposed on the upper semiconductor chip; and
a third wire connecting the metal layer and the redistribution layer to each other in the vertical direction,
wherein the third wire includes a first portion, a second portion, and a bonding surface, wherein the first portion is disposed in the lower molding layer, wherein the second portion is disposed in the upper molding layer, and wherein the first portion of the third wire and the second portion of the third wire are connected to each other at the bonding surface.

4. The semiconductor package according to claim 3, wherein
the bonding surface, at which the first portion of the second wire and the second portion of the second wire are connected to each other, and the bonding surface, at which the first portion of the third wire and the second portion of the third wire are connected to each other, are positioned on a same plane.

5. The semiconductor package according to claim 3, wherein
the third wire further includes a bonding surface at which the first portion of the third wire is connected to the redistribution layer, and
the bonding surface, at which the first portion of the third wire is connected to the redistribution layer, and the bonding surface, at which the first wire is connected to the redistribution layer, are positioned on the same plane.

6. The semiconductor package according to claim 3, wherein
the second portion of the second wire and the second portion of the third wire are exposed from the upper molding layer, and
the second portion of the second wire and the second portion of the third wire are bonded to the first portion of the second wire and the first portion of the third wire, respectively.

7. The semiconductor package according to claim 1, further comprising:
a package substrate; and
a logic chip disposed on the package substrate,
wherein the redistribution layer is disposed on the logic chip.

8. The semiconductor package according to claim 7, further comprising:
a first dummy chip disposed on the redistribution layer and covered by the lower molding layer; and
a second dummy chip disposed on the lower molding layer and covered by the upper molding layer.

9. The semiconductor package according to claim 8, wherein the first dummy chip and the second dummy chip overlap each other and are disposed on a central portion of the logic chip.

10. The semiconductor package according to claim 9, wherein the first dummy chip and the second dummy chip have different sizes from each other.

11. A semiconductor package, comprising:
a redistribution substrate;
a first semiconductor chip disposed on the redistribution substrate;
a first molding layer disposed on the redistribution substrate and covering the first semiconductor chip;
a redistribution layer disposed on the first semiconductor chip;
a chip stack including a second semiconductor chip and a third semiconductor chip stacked on the second semiconductor chip, in an offset manner, on the redistribution layer;
a second molding layer disposed below the third semiconductor chip and covering the second semiconductor chip;
a third molding layer disposed on the second molding layer and covering the third semiconductor chip;
a dummy chip disposed on one side of the chip stack;
a metal layer disposed on the third molding layer;
a first wire extending vertically to connect the second semiconductor chip to the redistribution layer;
a second wire extending vertically to connect the third semiconductor chip to the redistribution layer; and
a third wire extending vertically to connect the metal layer to the redistribution layer,
wherein the first wire includes a bonding surface that is formed at a boundary surface that is between the second molding layer and the redistribution layer, and
each of the second wire and the third wire includes a bonding surface, which is formed at a boundary surface that is between the second molding layer and the third molding layer, and a bonding surface, which is formed at a boundary surface between the second molding layer and the redistribution layer.

12. The semiconductor package according to claim 11, wherein the second wire includes wire segments that are divided at the bonding surface of the second wire, which is formed at the boundary surface that is between the second molding layer and the third molding layer, and the third wire includes wire segments that are divided at the bonding surface of the third wire, which is formed at the boundary surface that is between the second molding layer and the third molding layer.

13. The semiconductor package according to claim 11, wherein the dummy chip includes a first dummy chip and a second dummy chip, wherein the first dummy chip has a thickness corresponding to that of the second molding layer, and the second dummy chip has a thickness corresponding to that of the third molding layer.

14. The semiconductor package according to claim 13, wherein the chip stack is a plurality of chip stacks, and the plurality of chip stacks is disposed on two sides of the dummy chip, respectively.

15. A manufacturing method for a semiconductor package, the manufacturing method comprising:
disposing a metal layer on a carrier substrate;
disposing an upper memory chip on the carrier substrate;
forming a first bonding wire connecting the upper memory chip and the metal layer to each other;
forming an upper molding layer covering the upper memory chip and the first bonding wire;
grinding a portion of the upper molding layer so that a cut surface of the first bonding wire is formed;
offset stacking a lower memory chip with respect to the upper memory chip;
bonding the cut surface of the first bonding wire and a second bonding wire to each other;
forming a lower molding layer covering the lower memory chip and the second bonding wire; and
grinding a portion of the lower molding layer so that a cut surface of the second bonding wire is formed.

16. The manufacturing method according to claim 15, further comprising bonding the cut surface of the second bonding wire and a redistribution layer to each other.

17. The manufacturing method according to claim 16, further comprising:
disposing a logic chip, which includes a chip terminal, on the redistribution layer;
disposing a connection terminal on one side of the logic chip;
forming a logic chip molding layer on the redistribution layer to cover the logic chip and the connection terminal;
grinding the logic chip molding layer so that the chip terminal and a cut surface of the connection terminal are exposed; and
electrically connecting a cut surface of the chip terminal and the cut surface of the connection terminal to a package substrate.

18. The manufacturing method according to claim 15, further comprising:
disposing an upper dummy chip on one side of the upper memory chip on the carrier substrate; and
disposing a lower dummy chip on the upper dummy chip,
wherein the upper molding layer covers the upper memory chip, the upper dummy chip, and the first bonding wire, and
the lower molding layer covers the lower memory chip, the lower dummy chip, and the second bonding wire.

19. The manufacturing method according to claim 18, wherein the upper dummy chip has a different size from that of the lower dummy chip.

20. The manufacturing method according to claim 18, further comprising:
grinding a portion of the upper molding layer so that the cut surface of the first bonding wire and the upper dummy chip are exposed from the upper molding layer; and
grinding a portion of the lower molding layer so that the cut surface of the second bonding wire and the lower dummy chip are exposed from the lower molding layer.
